(19) United States
(12) Patent Application Publication
(10) Pub. No.: US 2013/0133926 A1
(43) Pub. Date: May 30, 2013

(54) BUILD-UP PRINTED CIRCUIT BOARD AND METHOD OF MANUFACTURING THE SAME

(71) Applicants: Tae Hoon Kim, Gyunggi-do (KR); Young Kwan Seo, Gyunggi-do (KR); Jun Young Kim, Seoul (KR); Sung Nam Cho, Gyunggi-do (KR)

(72) Inventors: Tae Hoon Kim, Gyunggi-do (KR); Young Kwan Seo, Gyunggi-do (KR); Jun Young Kim, Seoul (KR); Sung Nam Cho, Gyunggi-do (KR)

(73) Assignee: SAMSUNG ELECTRO-MECHANICS CO., LTD., Gyunggi-do (KR)

(21) Appl. No.: 13/409,067

(22) Filed: Feb. 29, 2012

(30) Foreign Application Priority Data
Nov. 25, 2011 (KR) 1020110124491

(51) Int. Cl. H05K 1/00; H05K 3/46; C25D 5/02; H05K 3/00

(52) U.S. Cl. 174/250; 427/97.3; 427/97.4; 156/280; 156/150; 205/125

(57) ABSTRACT

Disclosed herein is a method of manufacturing a build-up printed circuit board (PCB), the method including: providing a first resin substrate; forming a roughness by coating an epoxy emulsion solution on a surface of the first resin substrate; and providing a core layer by forming a core circuit layer on the first resin substrate on which the roughness is formed. According to the present invention, roughness of a substrate can be formed in an environment-friendly and economical way by introducing a process of coating epoxy emulsion on a resin substrate. Further, a highly reliable fine circuit can be implemented by enhancing an adhesive bond between a build-up board material and a metal circuit layer.

### CROSS REFERENCE TO RELATED APPLICATION

This application claims the benefit of Korean Patent Application No. 10-2011-0124491, filed on Nov. 25, 2011, entitled “Build-up Printed Circuit Board and Producing Method Thereof”, which is hereby incorporated by reference in its entirety into this application.

### BACKGROUND OF THE INVENTION

1. Technical Field

The present invention relates to a build-up printed circuit board and a method of manufacturing the same.

2. Description of the Related Art

A high density print board is required to accompany a high function electronic device and a high integration semiconductor device, and a current mainstream thereof is a multilayer board. A stacked bonding method and a build-up method are known as methods of manufacturing a multilayer printed circuit board (PCB).

The stacked bonding method, as disclosed in, for example, Japanese Patent Laid-Open Publication No. 62-205690, stacks a plurality of insulation substrates in which a predetermined conductive pattern is formed in one surface or both surfaces of the insulation substrates by using a prepreg functioning as protection of the conductive pattern, interlayer insulation thereof, and interlayer bonding thereof, and forms a multilayer PCB by a press molding. In general, a through hall is installed in a place requiring an electrical conduction between conductive patterns of multilayer, and the through hall is plated for the electrical conduction.

Further, the build-up method of forming a circuit by etching a copper stacked substrate having a plated through hall, masking the circuit by using an insulation resin, printing a conductive paste ink thereon, forming a circuit, forming a chemical copper plating coating film in the conductive paste ink and the through hall, and repeating these processes to form a multilayer PCB is disclosed in Japanese Patent Laid-Open Publication No. 57-72398.

However, a space for storing a wire substrate constituting an electric circuit accompanying with a variety of small-size and thin electronic devices is quite limited. To store the wire substrate constituting the electric circuit in the limited space, the build-up method capable of thinning and high density rather than the stacked bonding method is used to manufacture a PCB.

Meanwhile, a subtractive process, a modified semi additive process (MSAP), a semi additive process (SAP), etc. are currently used to manufacture a build-up PCB. In particular, the subtractive process is applied to a high density interconnection (HDI) product, the subtractive process and the MSAP are applied to a ultra thin-chip scale package (UT-CSP), and a ball grid array (BGA), the subtractive process is applied to a core layer of a flip chip ball grid array (FCBGA), the SAP is applied to a build-up exterior layer, and an electroless plating process is used to form a seed layer and implement a fine circuit. A conventional SAP forms a metal seed layer through a wet process to which wet surface processing and electropless plating are applied, which increases surface roughness, making it difficult to implement the fine circuit, and produces a large amount of wastes, being environment-unfriendly.

### SUMMARY OF THE INVENTION

As a result of conducting a wide range of researches in order to solve the problems, a build-up printed circuit board (PCB) capable of implementing an environment-friendly and reliable fine circuit can be manufactured by spraying epoxy emulsion onto a semi-curing dry basic material, forming roughness in the build-up PCB, post-curing and forming roughness in an insulation layer, and thus the present invention is completed.

The present invention has been made in an effort to provide a method of manufacturing a build-up PCB including a core layer and an exterior layer capable of forming roughness of a substrate in an environment-friendly and economical way by introducing a process of coating epoxy emulsion during manufacturing of the build-up PCB.

Further, the present invention has been made in an effort to provide a build-up PCB capable of implementing a highly reliable fine circuit by enhancing an interface bonding force between a resin substrate and a metal layer.

According to a first preferred embodiment of the present invention, there is provided a method of manufacturing a build-up printed circuit board (PCB), the method including: providing a first resin substrate; forming a roughness by coating an epoxy emulsion solution on a surface of the first resin substrate; and providing a core layer by forming a core circuit layer on the first resin substrate on which the roughness is formed.

The method may further include, on the core layer, stacking a second resin substrate; forming a roughness by coating the epoxy emulsion solution on a surface of the stacked second resin substrate; and providing an exterior layer by forming an exterior circuit layer on the second resin substrate on which the roughness is formed.

The core circuit layer may be manufactured by forming a first metal seed layer on the first resin substrate on which the roughness is formed, forming a first metal pattern plating layer on the first resin substrate on which the first metal seed layer is formed using electroplating, and removing the first metal seed layer from a portion of the first resin substrate on which the first metal pattern plating layer is not formed.

The exterior circuit layer may be manufactured by forming a second metal seed layer on the second resin substrate on which the roughness is formed using electroless plating, forming a second metal pattern plating layer on the second resin substrate on which the second metal seed layer is formed using electroplating, and removing the second metal seed layer from a portion of the second resin substrate on which the second metal pattern plating layer is not formed.

The providing of the first resin substrate may include: forming a conduction hole in the first resin substrate.

The stacking of the second resin substrate may include: forming a blind via hole on the stacked second resin substrate.

The forming of the roughness may include: coating epoxy emulsion, post-curing the coated epoxy emulsion at a temperature of 80˜200° C., and drying the post-cured epoxy emulsion.

The epoxy emulsion may include a surfactant, a solvent, a curing agent, and epoxy resin.

Sizes of particles of the epoxy emulsion may be 1˜30 μm.

A thickness of the coated epoxy emulsion may be 2˜8 μm.

The first and second resin substrates may be epoxy based resin or fluorine based resin substrates that are the same as or different from each other.

The first metal seed layer may be formed by using vacuum evaporation or electroless plating.

An average surface roughness of the resin substrate formed by coating the epoxy emulsion may be less than 1.0 μm.

According to a second preferred embodiment of the present invention, there is provided a build-up PCB formed by the method of manufacturing the same as described above.

An average surface roughness of the build-up PCB may be less than 1.0 μm.

### BRIEF DESCRIPTION OF THE DRAWINGS

FIGS. 1A and 1B are schematic flowcharts for explaining a process of manufacturing a core layer and an exterior layer of a build-up printed circuit board (PCB) according to one embodiment of the present invention;

FIGS. 2A through 2G are schematic diagrams for explaining a process of manufacturing a core layer of a build-up PCB according to one embodiment of the present invention;

FIG. 3 is a schematic diagram for explaining a process of coating epoxy emulsion on a build-up PCB according to one embodiment of the present invention;

FIGS. 4A through 4F are schematic diagrams for explaining a process of forming a first exterior layer on a core layer of FIG. 2G; and

FIG. 5 is a cross-sectional view of a FCBGA PCB manufactured by forming a second exterior layer on the first exterior layer of FIG. 4F.

### DESCRIPTION OF THE PREFERRED EMBODIMENTS

Hereinafter, exemplary embodiments will be described in detail with reference to the accompanying drawings so that they can be easily practiced by those skilled in the art to which the present invention pertains.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

Therefore, the configurations described in the embodiments and drawings of the present invention are merely most preferable embodiments but do not represent all of the technical spirit of the present invention. Thus, the present invention should be construed as including all the changes, equivalents, and substitutions included in the spirit and scope of the present invention at the time of filing this application.

The embodiments of the present invention will now be described in detail with reference to accompanying drawings below.

As described above, although a conventional process for a core layer of a build-up printed circuit board (PCB) stacks dry films using a subtractive process by using a resin substrate having both surfaces in which metal layers are stacked and implements a circuit by wet etching after exposure and developing of the dry films, a circuit line width having a pitch of 80 μm (Line/Space=40/40 μm) or less is limited implemented. Meanwhile, in order to overcome such a limitation of a fine circuit, a method of forming the circuit by electroplating and flash etching after processing a via hole in a substrate using a semi additive process (SAP), performing a desmear process, and forming a metal seed layer by electroless plating may be considered. However, if a circuit layer is formed by electroless plating and electroplating by using a general wet process by applying the SAP, an adhesive bond between the resin substrate and the metal layer is not secured, which makes it difficult to implement the fine circuit.

According to an embodiment of the present invention, in order to solve the above-described problem, the SAP is applied to manufacture the core layer, the wet desmear process on the resin substrate of the core layer to form roughness of the conventional wet metal seed layer is replaced with a dry process of forming roughness by coating epoxy emulsion, which enhances a peel strength of metal having 0-8 Kgf/cm or higher by using an environment-friendly SAP, and thus high density fine circuit can be implemented, whereas the conventional wet desmear process on a build-up exterior layer is replaced with a process of coating epoxy emulsion to form roughness of the resin substrate and form the circuit layer, and thus the high density fine circuit can be implemented by applying the SAP onto all layers.

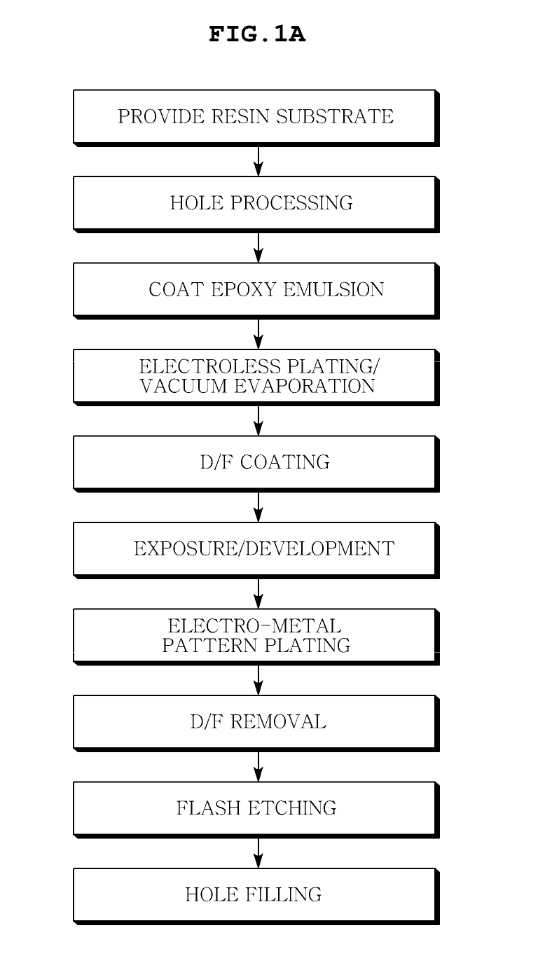

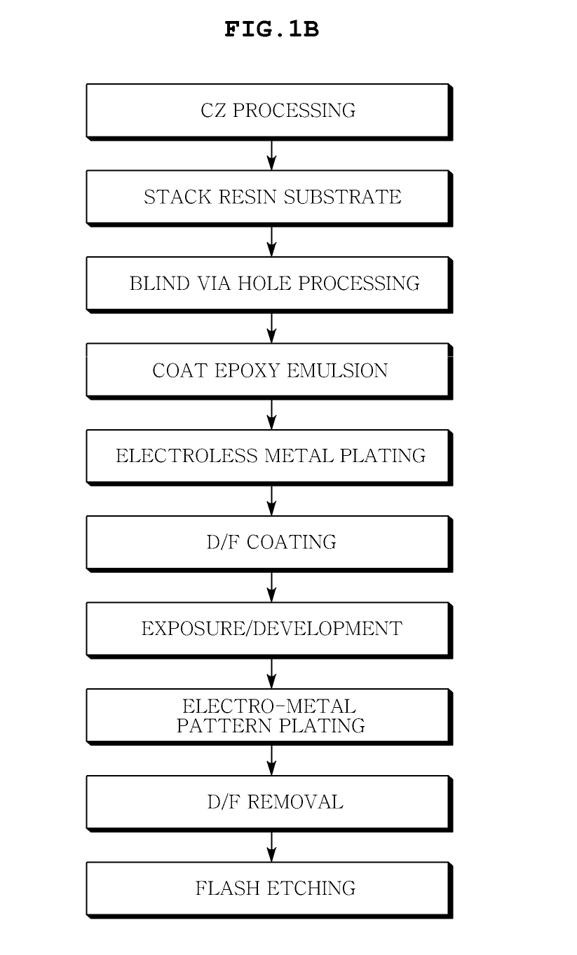

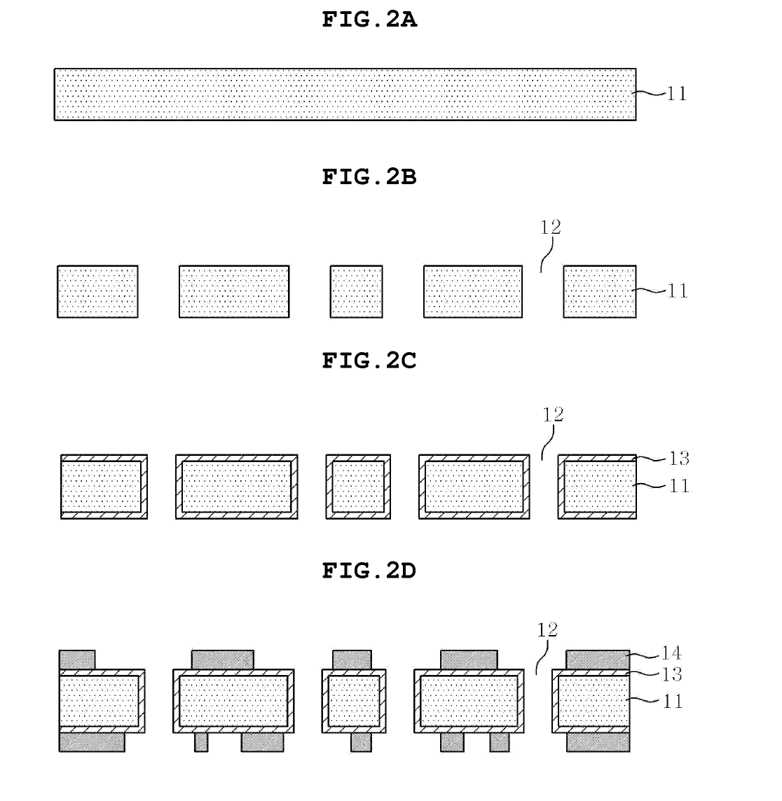

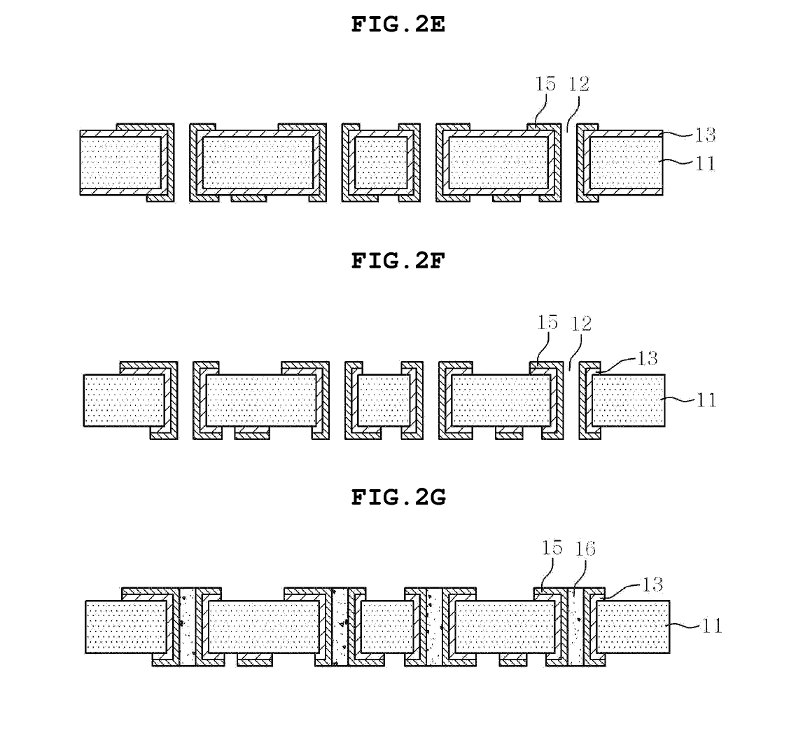

FIGS. 1A and 1B are schematic flowcharts for explaining a process of manufacturing a core layer and an exterior layer of a build-up printed circuit board (PCB) according to one embodiment of the present invention. FIGS. 2A through 2G are schematic diagrams for explaining a process of manufacturing a core layer of a build-up PCB according to one embodiment of the present invention.

Referring to FIGS. 1A and 2A through 2H, a resin substrate 11 for a PCB that is used by one of ordinary skill in the art and is formed of a general epoxy based resin or fluorine based resin is prepared (see FIG. 2A). Thereafter, at least one conduction hole 12 for an interior layer via is formed in the resin substrate 11 for an interlayer electrical conduction (see FIG. 2B). Roughness of a surface of the resin substrate 11 is formed by coating epoxy emulsion on the surface of the resin substrate 11 in which the conduction hole 12 is formed.

The process of forming roughness of the resin substrate 11 by coating the epoxy emulsion may be preferably performed by coating the epoxy emulsion, post-curing the coated epoxy emulsion at a temperature from 80˜200° C., and drying the post-cured epoxy emulsion. However, the present invention is not particularly limited thereto, and it will be obvious to one of ordinary skill in the art that an actual processing condition can be appropriately regulated according to a substrate material.

The epoxy emulsion is prepared by adding epoxy resin, a surfactant, and a curing agent to a solvent and forcibly spreading the solvent. The epoxy emulsion is prepared by using the same method as an emulsion paint or an emulsion adhesive that is commonly used in the art, and may be configured as a ratio of the surfactant of 10˜30 wt %, the curing agent of 5˜15 wt %, and the solvent of 200˜400wt % with respect to the epoxy resin of 100 wt % in order to achieve the effect of the present invention but the present invention is not limited thereto.

In this regard, sodium dodecyl benzene sulfonate (SDBS), pluronic F127 (BASF), polyoxyethylene nonylphenyl ether, etc, may be used as the surfactant. Sizes of particles of the epoxy emulsion may be adjusted according to a type of the surfactant, and may be forcibly emulsified to sizes of 1˜30 μm.

Further, an amine-based epoxy curing agent such as ethylene diamine, aminoethyl piperazine (AEP) may be used as the curing agent. It will be effective to generally use de-ionize water as the solvent.

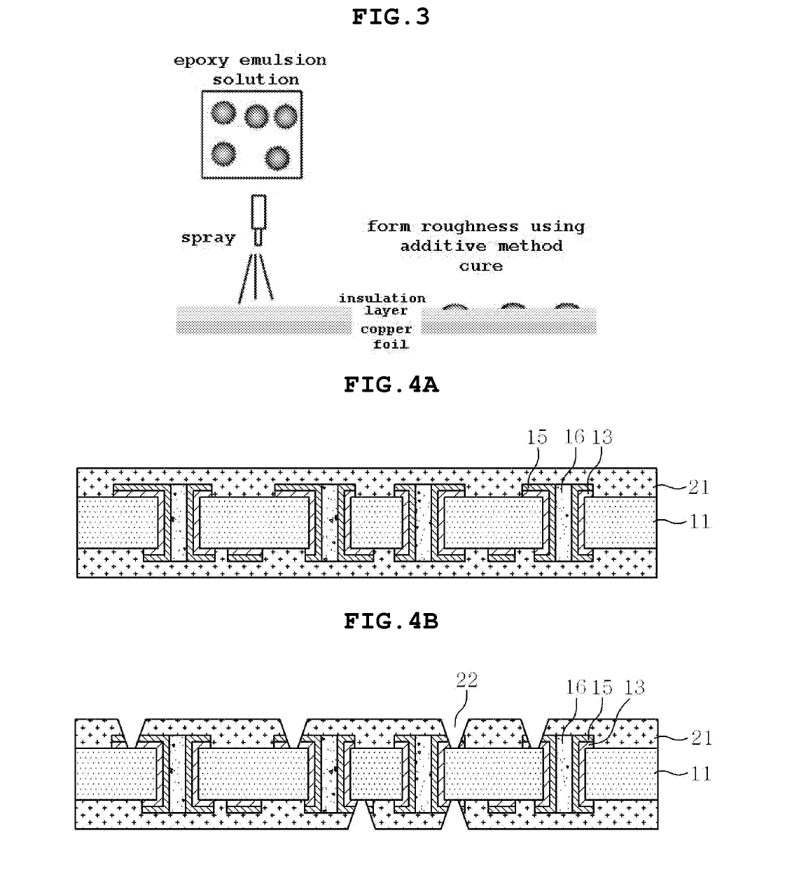

As such, the process of forming roughness of the resin substrate 11 by coating the epoxy emulsion can reinforce an adhesive bond between the resin substrate 11 and a metal seed layer that will be formed at a subsequent process. That is, as shown in FIG. 3, roughness of the resin substrate 11 is formed by coating the epoxy emulsion on a surface of a polymer material of the resin substrate 11 by using spray, dipping, or various coating methods known to one of ordinary skill in the art, curing the coated resin substrate 11 at a temperature of 80° C. or higher, and drying the cured resin substrate 11, which reinforces the adhesive bond of the material interface, thereby implementing the fine circuit. In this regard, a thickness of the coated epoxy emulsion may be preferably 2˜8 μm, more preferably 5˜6 μm in order to achieve the effect of the present invention.

By using the method of coating the epoxy emulsion, an excellent bonding strength can be maintained while a roughness value of the resin substrate 11 is much smaller than that of the given desmear method since a size of emulsified epoxy can be freely adjusted, and thus an area of the whole resin substrate 11 for forming roughness can be widely and uniformly formed. If an average measurement value Ra of the formed roughness is greater than 1 μm, it is disadvantageous to form a fine circuit line width, and if the average measurement value Ra of the formed roughness is smaller than 1 μm, the fine circuit line width can be formed. If the average measurement value Ra of the formed roughness by using the method is smaller than 0.5˜0.7 μm, a high bonding strength of 1 kgf/cm can be obtained.

Next, referring to FIG. 2C, a metal seed layer 13 having a desired thickness is formed by perforating electroless plating or vacuum evaporation metal on the resin substrate 11 having the epoxy emulsified surface. In this regard, the vacuum evaporation may be preferably performed through sputtering, thermal evaporation, or e-beaming. However, if it is known to one of ordinary skill in the art, the present invention is not particularly limited thereto. A thickness of the metal seed layer 13 may be 0.02˜4 μm, preferably 0.02˜1 μm, and more preferably 0.02˜0.5 μm.

Thereafter, as known to one of ordinary skill in the art, a metal pattern plating layer 15 is formed by coating a dry film that will function as a plating resist on a predetermined part of the metal seed layer 13 excluding a part on which pattern plating is to be performed (see FIG. 2D), performing the pattern plating of electro-metal, and removing the dry film 14 (see FIG. 2E).

Meanwhile, a core circuit layer is completed by removing the metal seed layer 13 on which the metal pattern plating layer 15 is not formed by using a usual flash etching method (see FIG. 2F), and filling the conduction hole 12 in which the metal pattern plating layer 15 is formed with a usual conductive metal paste 16 known to one of ordinary skill in the art (see FIG. 2G).

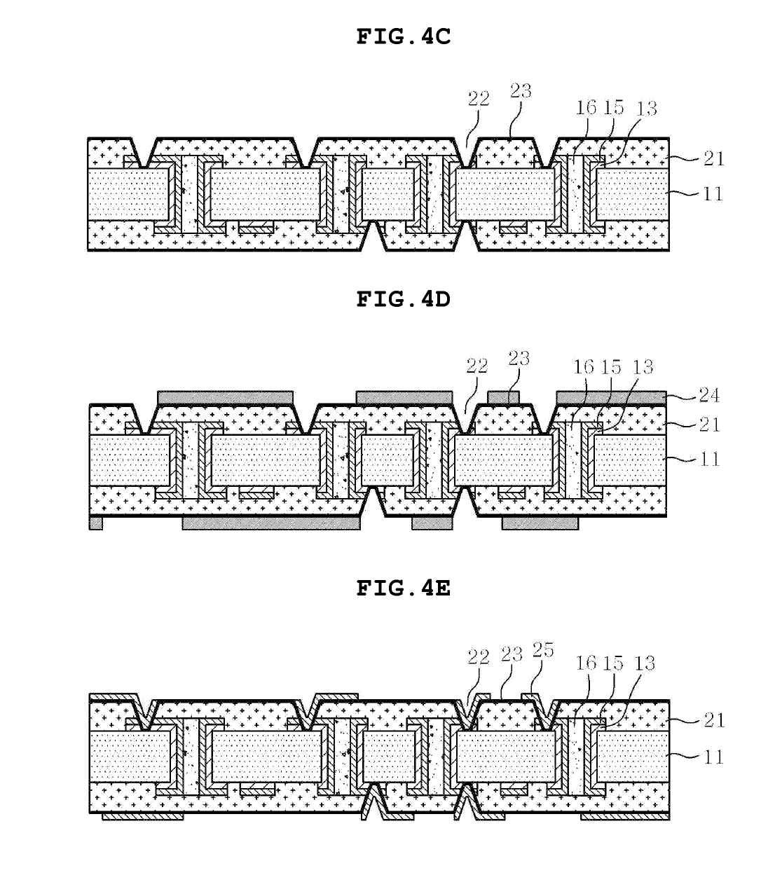

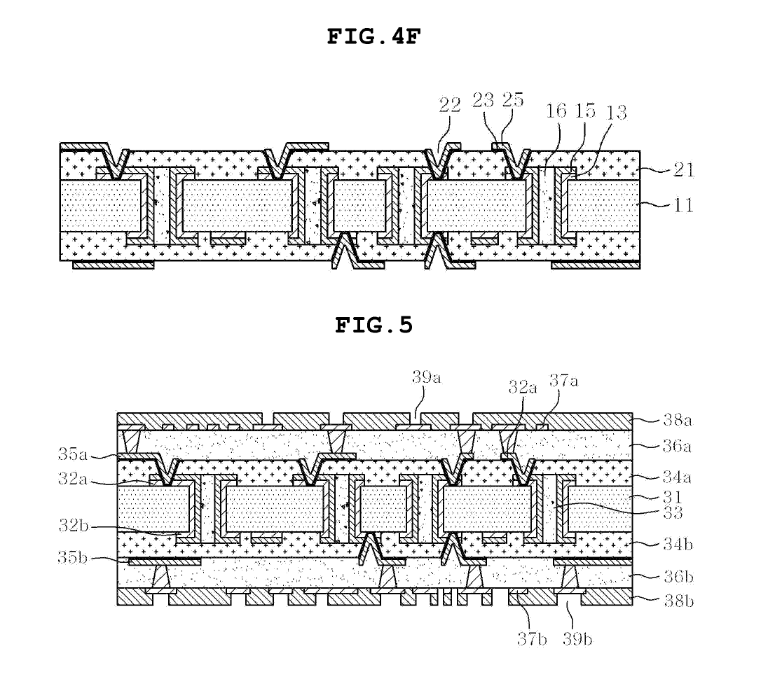

A process of building-up an exterior layer on a core layer of a build-up PCB according to a preferred embodiment of the present invention will now be described with reference to FIGS. 1B and 4A through 4F.

An adhesive bond between the core circuit layer formed in FIG. 2G and a resin substrate material is secured by increasing roughness of a surface of the core circuit layer using a general surface processing method, for example, CZ processing (CZ8100 of MEC company), and an epoxy resin or fluorine resin based substrate 21 that is the same as or different from used in the core circuit layer is stacked thereon (see FIG. 4A).

Then, a blind via hole 22 for an interlayer electrical conduction is formed on the epoxy resin or fluorine resin based substrate 21 (see FIG. 4B), roughness of a surface of the epoxy resin or fluorine resin based substrate 21 is formed through a process of coating epoxy emulsion, and a metal seed layer 23 having a thickness of, for example, about 2˜3 μm is formed by performing electroless plating (see FIG. 4C).

Thereafter, a dry film 24 is coated on a predetermined position of the metal seed layer 23 excluding a position where a circuit pattern is to be formed including the blind via hole 22 (see FIG. 4D), and a metal pattern plating layer 25 is formed through electroplating by using the dry film 24 as a resist (see FIG. 4E).

Then, the dry film 24 is removed, and the metal seed layer 23 on which the metal pattern plating layer 25 is not formed is removed through a usual flash etching process, and thus an exterior circuit layer is completely formed (see FIG. 4F).

Selectively, after forming third through sixth layers by repeating a SAP two times as described with reference to FIGS. 4A through 4F, for example, if the exterior circuit layer is applied as an outermost exterior layer of a FCBGA substrate, as known to one of ordinary skill in the art, a bump can be formed by coating a solder resist, forming a usual solder resist opening unit through a usual solder resist opening process, and performing a usual electroless nickel and gold plating. An example of a six-layer FCBGA substrate formed according to the above processes is shown in FIGS. 4A through 4F.

Referring to FIG. 5, first circuit layers 32a and 32b and a via hole 33 are formed in a first resin substrate 31 as a core layer, second circuit layers 35a and 35b are formed with second resin substrates 34a and 34b as exterior layers and a blind via hole, and third circuit layers 37a and 37b are formed with third resin substrates 36a and 36b and a blind via hole. Further, solder resists 38a and 38b are formed on an outermost exterior layer, and solder resist opening units 39a and 39b are formed according to a predetermined opening process.

Meanwhile, a process of building-up exterior layers may be repeatedly performed several times according to a purpose of using the build-up board, and a predetermined subsequent process may be further performed.

The build-up PCB manufactured as described above is not particularly limited to a high density interconnection (HDI) product, a ultra thin-chip scale package (UT-CSP), a ball grid array (BGA), a flip chip ball grid array (FCBGA), etc. and may be applied to all products for implementing a fine circuit.

As described above, according to a process of manufacturing the build-up PCB of the present invention, roughness of a surface of the build-up PCB is formed by coating epoxy emulsion on the surface thereof, which increases an adhesive bond (i.e., peel strength>0.8 kgf/cm) between the build-up PCB and metal, and thus a fine circuit can be implemented, and a given process of forming a wet metal seed layer is replaced with a dry process, and thus a fine circuit of a core layer having a minimum surface roughness (Ra<1.0 μm) can be implemented through an environment-friendly process. Further, a circuit is formed by applying a SAP to the whole layers of the build-up PCB including the core layer and the exterior layers, and thus a highly reliable high density fine circuit can be advantageously formed.

The present invention will now be described in more detail through the embodiments below but the scope of the present invention is not limited thereto.

### PREPARATION EXAMPLE 1

Preparation of Epoxy Emulsion

Epoxy resin (YDCN-500-90P) of 300 g and a surfactant (SDBS) of 60 g were melt in a dry oven for one hour at a temperature of about 120° C., the melt solution was cooled at a temperature of 70˜80°C., and a curing agent AEP of 10 wt % with respect to an epoxy weight was mixed with the solution. Then, a solid content of about 25 wt % was added to de-ionize water of 50° C. or higher to produce reverse emulsion, and a high speed homogenizer was forcibly mixed at an agitating speed of 12,000 rpm, and thus epoxy emulsion was prepared.

### EXAMPLE 1

A. A via hole of about 100˜300 μm was formed in an epoxy resin substrate by using a computer numerical control (CNC) drill that is a mechanical drill, the prepared epoxy emulsion was coated on the epoxy resin substrate by using spray, and a surface roughness of the epoxy resin substrate was formed. Then, a Cu seed layer was deposited on the epoxy resin substrate in which the via hole was formed by using electroless plating. Thereafter, a pattern copper plating layer of about 10˜20 μm was formed through electro copper pattern plating at H₂SO₄ (120˜160 gl/l), Cu (20˜40 g/l), Cl (20˜50 ppm), Cupracid HL leveler (5-15 ml/l), air flow volume (0.05˜0.15 m³/min), a temperature (20˜25° C.), and a current density (F/B1.5ASD), and the Cu seed layer was removed by performing flash etching by using a H₂SO₄/H₂O₂ etching solution at an etching speed of 2 m/min. Finally, a core circuit layer was completely formed by filing the via hole at conditions of a copper paste having a viscosity of 3.0 pa·s, preheating of 80° C./60 min, and curing of 160° C./60 min.

B. An adhesive bond between the core circuit layer and a substrate material was secured by increasing roughness of the copper surface through CZ processing (CZ8100 of MEC company), an Ajinomoto build up film (ABF) was tack welded by a primary vacuum lamination equipment at a temperature of 100° C., a vacuum time of 30 sec, a pressure of 7 (Kgf/cm²), and a pressing time of sec, and was deposited in secondary hot pressing at the temperature of 100° C., the pressure of 10 (Kgf/cm²), and the pressing time of 90 sec. Then, a blind via hole of about 70 μm was formed by using Co₂ laser, epoxy emulsion is coated on the resin substrate by using spray, and a surface roughness of the resin substrate was formed. Then, a Cu seed layer having a thickness of about 3 μm was formed through electroless copper plating (Atotech, ATOTECH company). Thereafter, a pattern copper plating layer of about 15 μm was formed through electro copper pattern plating (Evara, EVARA company) at H₂SO₄ (120˜160 g/l), Cu (20˜40 g/l), Cl (20˜50 ppm), Cupracid HL leveler (5-15 ml/l), air flow volume (0.05˜0.15 m³/min), a temperature (20˜25° C.), and a current density (F/B1.5ASD), and the Cu seed layer was removed by performing flash etching by using the H₂SO₄/H₂O₂ etching solution at an etching speed of 2 m/min.

C. Third through sixth exterior layers were formed by repeatedly building-up the substrate obtained in the process B two times in the same manner as the process B, a solder resist was coated at a roll pitch (370 μm, 350 μm, 320 μm, a roll press), a doctor bar pressure, a roll rotation speed (1.2˜1.6 m/min), and a drying temperature/time (78° C.±2° C.), a solvent contained in an ink was removed through a process of half-curing a surface of the ink coated by primarily coating and drying (a tact time of 30 sec) a pre-cure and secondarily coating and drying (the tact time of 30 sec) the pre-cure, and was dried thus an exposure process could be performed. UV light was irradiated onto the coated ink surface at an UV intensity of spec: 700˜900 mJ/cm² in the exposure process and passes through a work film and a glass mask so that ink light curing is induced, and thus the ink functioned as a resist of a developing solution. During a developing process, a sodium carbonate (Na₂CO₃ of 1%) functioned as a resist in a part where light curing was performed whereas a part where light curing was not performed was dissolved, a solution was UV cured (a solder resist property was enhanced by adding light curing on the ink surface when the developing process was complete and additionally performing a weak light reaction during an UV exposure) by using a Na₂CO₃ density: 11±1.0 g/l (spec:10.5±2.0 g/l), Na₂CO₃ pH: 10.0˜12.5, a Na₂CO₃ temperature: 30±3° C., a developing pressure, a developing speed, a Na₂CO₃ solution (sodium carbonate of 1%), double coupling of a curing agent component of ink components was activated in order to enhance an adhesive bond between the cured (completely dried) ink and Cu interface and increase hardness of the ink, and all resin exhibiting in the curing agent finally reacted during post-curing, and thus a polymer was completed. A circuit pattern of a position to which a bump is to be formed was opened through solder opening at temperature/time: 120° C./30 min and 150° C./60 min, electroless nickel plating under conditions of boric acid density: 22˜38 g/l, PH: 3.5˜4.5, nickel sulfamate: 400˜500 g/l, nickel chloride: 8˜16 g/l, Fe: less than 200 ppm, Cu: less than 200 ppm, and temperature: 45˜55° C., and electroless gold plating under conditions of Au density: 5.5˜7.5 g/l, PH: 6.1˜6.4, gravity: 1.09˜1.24, Fe: less than 50 ppm, Cu: less than 18 ppm, Ni: less than 350 ppm, Zn: less than 5 ppm, Tl: 5˜15 ppm, and temperature: 65˜75° C. were sequentially performed, and thus a FCBGA substrate was manufactured.

Results obtained by measuring a bonding intensity of the build-up PCB and a surface roughness of an insulation material thereof are shown in Table 1 below in which a roughness is formed during the process A by using a Newview 7200 model of Zygo company used as 3D optical surface profilers, roughness of five points is evaluated, and an average of the five points is used as a roughness value.

### EXAMPLE 2

A CBGA substrate was manufactured in the same manner as described in Example 1 except that an ion beam sputter was used instead of using the electroless plating method during the process A of Example 1.

Results obtained by measuring a bonding intensity of a build-up PCB and a surface roughness of an insulation material thereof are shown in Table 1 below.

### COMPARATIVE EXAMPLE 1

A CBGA substrate was manufactured in the same manner as described in Example 1 except that the process of forming a surface roughness using the epoxy emulsion in the process A of Example 1 was skipped and the following usual desmear processing was used.

Results obtained by measuring a bonding intensity of a build-up PCB and a surface roughness of an insulation material thereof are shown in Table 1 below.

Desmear

Sweller (having pH 10˜12 functioning as a conditioner for optimal etching, i.e. making smear swollen)→third stage water cleaning→permanganic acid processing (smear that is a main object was removed and a roughness was formed on a resin surface)→first stage water cleaning→second stage water cleaning→neutralization (a process of neutralizing remaining manganese dioxide)→third stage water cleaning→drying

TABLE 1

| | | | Comparative |
|---|---|---|---|
| | Example 1 | Example 2 | Example 1 |
| Adhesive bond | 0.8 kgf/cm | 1.0 kgf/cm | 0.5 kgf/cm |
| (peel strength) | | | |
| Surface roughness | 0.9 μm | 0.9 μm | 1.0 μm |

As shown in Table 1 above, when a build-up board is manufactured by using a given wet desmear process (Comparative Example 1), the adhesive bond is about 0.5 kgf/cm and the surface roughness is 1.0 μm, and thus a fine circuit having a pitch of 36 μm (Line/Space=18/18 μm) can be implemented, whereas when a build-up board is manufactured by coating epoxy emulsion and using surface processing according to the present invention (Examples 1 and 2), the adhesive bond is about 0.9 kgf/cm and the surface roughness is 0.9 μm, which are relatively quite smaller than those of Comparative Example 1, and thus a fine circuit having a pitch of 20 μm (Line/Space=10/10 μm) can be implemented, and a faster signal transmission speed can be implemented than that of Comparative Example 1.

As described above, roughness of a substrate can be formed in an environment-friendly and economical way by introducing a process of coating epoxy emulsion on a resin substrate. Further, a highly reliable fine circuit can be implemented by enhancing an adhesive bond between a build-up board material and a metal circuit layer.

Although the preferred embodiments of the present invention have been disclosed for illustrative purposes, they are for specifically explaining the present invention. Therefore, a build-up printed circuit board and a method of manufacturing the same according to the preferred embodiments of the present invention are not limited thereto, but those skilled in the art will appreciate that various modifications and alteration are possible, without departing from the scope and spirit of the invention as disclosed in the accompanying claims. Accordingly, such modifications and alterations should also be understood to fall within the scope of the present invention. A specific protective scope of the present invention could be defined by accompanying claims.

What is claimed is:

1. A method of manufacturing a build-up printed circuit board (PCB), the method comprising:
providing a first resin substrate;
forming a roughness by coating an epoxy emulsion solution on a surface of the first resin substrate; and
providing a core layer by forming a core circuit layer on the first resin substrate on which the roughness is formed.

2. The method as set forth in claim 1, further comprising: on the core layer,
stacking a second resin substrate;
forming a roughness by coating the epoxy emulsion solution on a surface of the stacked second resin substrate; and
providing an exterior layer by forming an exterior circuit layer on the second resin substrate on which the roughness is formed.

3. The method as set forth in claim 1, wherein the core circuit layer is manufactured by forming a first metal seed layer on the first resin substrate on which the roughness is formed, forming a first metal pattern plating layer on the first resin substrate on which the first metal seed layer is formed using electroplating, and removing the first metal seed layer from a portion of the first resin substrate on which the first metal pattern plating layer is not formed.

4. The method as set forth in claim 2, wherein the exterior circuit layer is manufactured by forming a second metal seed layer on the second resin substrate on which the roughness is formed using electroless plating, forming a second metal pattern plating layer on the second resin substrate on which the second metal seed layer is formed using electroplating, and removing the second metal seed layer from a portion of the second resin substrate on which the second metal pattern plating layer is not formed.

5. The method as set forth in claim 1, wherein the providing of the first resin substrate includes forming a conduction hole in the first resin substrate.

6. The method as set forth in claim 2, wherein the stacking of the second resin substrate includes forming a blind via hole on the stacked second resin substrate.

7. The method as set forth in claim 1, wherein the forming of the roughness includes coating epoxy emulsion, post-curing the coated epoxy emulsion at a temperature of 80˜200° C., and drying the post-cured epoxy emulsion.

8. The method as set forth in claim 1, wherein the epoxy emulsion includes a surfactant, a solvent, a curing agent, and epoxy resin.

9. The method as set forth in claim 1, wherein sizes of particles of the epoxy emulsion are 1˜30 μm.

10. The method as set forth in claim 1, wherein a thickness of the coated epoxy emulsion is 2˜8 μm.

11. The method as set forth in claim 2, wherein the first and second resin substrates are epoxy based resin or fluorine based resin substrates that are the same as or different from each other.

12. The method as set forth in claim 3, wherein the first metal seed layer is formed by using vacuum evaporation or electroless plating.

13. The method as set forth in claim 1, wherein an average surface roughness of the resin substrate formed by coating the epoxy emulsion is less than 1.0 μm.

14. A build-up PCB formed by the method of manufacturing the same as set forth in claim 1.

15. The build-up PCB as set forth in claim 14, wherein an average surface roughness of the build-up PCB is less than 1.0 μm.
